(19) United States
(12) Patent Application Publication
(10) Pub. No.: US 2010/0148314 A1
(43) Pub. Date: Jun. 17, 2010

(54) SEMICONDUCTOR DEVICE AND METHOD FOR MANUFACURING THE SAME

(76) Inventor: Jin Woo Han, Seoul (KR)

Correspondence Address: SALIWANCHIK LLOYD & SALIWANCHIK;A PROFESSIONAL ASSOCIATION, PO Box 142950, GAINESVILLE, FL, 32614, US

(21) Appl. No.: 12/630,282

(22) Filed: Dec. 3, 2009

(30) Foreign Application Priority Data
Dec. 16, 2008 (KR) 10-2008-0128143

(51) Int. Cl. H01L 23/544; H01L 21/762

(52) U.S. Cl. 257/620; 438/424; 257/E23.179; 257/E21.546

(57) ABSTRACT

The present invention provides a semiconductor device and a method for manufacturing the same capable of inhibiting plasma damage. A semiconductor device according to one embodiment includes a protective pattern grounded to a semiconductor substrate in a scribe line area, on a wafer including a main chip area and the scribe line area formed around the main chip area. Plasma arching defects to a wafer can be reduced by forming a plasma arching protective pattern in a scribe line region and effectively using the scribe line region in an unused region of the wafer.

### CROSS-REFERENCE TO RELATED APPLICATION

This application claims the benefit under 35 U.S.C. §119 of Korean Patent Application No. 10-2008-0128143, filed Dec. 16, 2008, which is hereby incorporated by reference in its entirety.

### BACKGROUND

Currently, the high integration of a semiconductor device has been advanced by the development of a photo-lithography technology. A photo-lithography process is a process that transfers a geometrical pattern on a mask to a photosensitive material covering a surface of the semiconductor wafer, that is, a thin layer of a resist.

In addition, the high integration has been advanced by the development of an etching process, for example, a plasma process, a reactive ion etching (RIE) process, etc.

In order to manufacture a high-integrated semiconductor device and a high-speed semiconductor device, a process of forming a multi-metal layer is required. In this case, the plasma process is applied and the use of the plasma process has been gradually increased. The process of forming the multi-metal layer is often a process forming a metal layer of 5-layers or 6-layers.

As such, as the integration of the semiconductor device is increased, a line width of a device circuit is narrow, such that a high density plasma (HDP) etching is used in order to etch the narrow line width.

As described above, the high density plasma is used, which forms a strong electrical field between a gate of the semiconductor device and a substrate, thereby generating a serious charging damage for a gate insulating layer.

The damage occurring in the high density plasma process includes damage to the gate insulating layer at a circuit in the device, such that a shift of threshold voltage (Vth), a sub threshold slope, metal conductance (Gm), degradation of drain current (Idsat), and lifetime reduction of gate insulating layer conductance (Gox), etc., occur, thereby causing the malfunction of the semiconductor device.

### BRIEF SUMMARY

An embodiment provides a semiconductor device and a method for manufacturing the same capable of inhibiting a plasma arching defect by inserting a pattern in a scribe line.

A semiconductor device according to an embodiment includes a protective pattern grounded to a semiconductor substrate in a scribe line region, on a wafer including a main chip region and the scribe line region formed around the main chip region.

A method of manufacturing a semiconductor device according to an embodiment forms a protective pattern including a metal pattern connected to a semiconductor substrate and a protective line connected to the metal pattern in a scribe line region, in a process of forming a via metal and a metal wiring of the semiconductor device in the main chip region.

A semiconductor device according to an embodiment includes: transistors formed on a semiconductor substrate in a main chip region; a metal wiring layer formed on the semiconductor substrate in the main chip region and including metal wirings connected to the transistors; and a protective pattern formed on the metal wiring layer in a scribe line region outside the main chip region, wherein the protective pattern is grounded to the semiconductor substrate and is connected to a top layer of the metal wiring layer in the scribe line region.

### BRIEF DESCRIPTION OF THE DRAWINGS

FIG. 1 is a plan view showing a wafer.

FIG. 2 is a cross-sectional view showing a plasma etching process of a semiconductor device according to the embodiment.

FIG. 3 is a cross-sectional view showing a plasma etching process of a semiconductor device according to another embodiment.

FIG. 4 is a plan view showing four main chip regions and scribe line regions around the main chip regions at the semiconductor device according to an embodiment.

FIG. 5 is a plan view showing 16 main chip regions and scribe line regions around the main chip regions at the semiconductor device according to an embodiment.

### DETAILED DESCRIPTION

Hereinafter, a semiconductor device and a method for manufacturing the same according to exemplary embodiments of the present invention will be described with reference to the accompanying drawings.

In the description of embodiments, it will be understood that when a layer (or film) is referred to as being ‘on’ another layer or substrate, it can be directly on another layer or substrate, or intervening layers may also be present. Further, it will be understood that when a layer is referred to as being ‘under’ another layer, it can be directly under another layer, or one or more intervening layers may also be present. In addition, it will also be understood that when a layer is referred to as being ‘between’ two layers, it can be the only layer between the two layers, or one or more intervening layers may also be present. In the description, when a layer is referred to as being “connected” to another layer, the layer can directly contact and/or be electrically connected to the other layer.

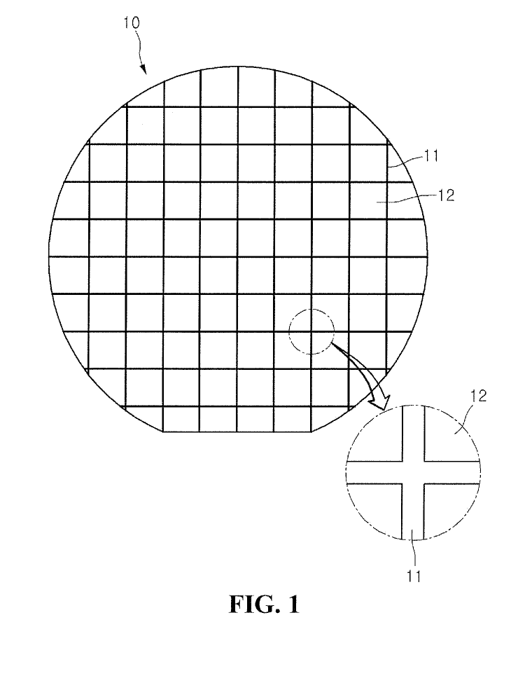

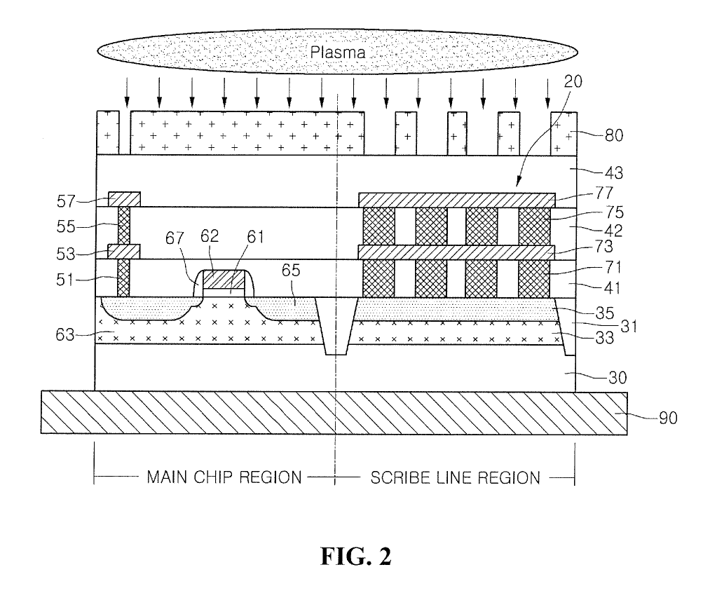

FIG. 1 is a plan view showing a wafer, and FIG. 2 is a cross-sectional view showing a plasma etching process of a semiconductor device according to an embodiment.

Referring to FIG. 1, a wafer 10 is formed with a main chip region 12 in which a semiconductor chip is formed and a scribe line region 11 in which a scribe line is formed.

The scribe line, which is a region removed in a sawing process for individualizing the main chip, is formed along a circumference of the main chip.

The main chip region 12 is formed with various devices, such as transistors, capacitors, metal wirings, and vias.

The scribe line region 11 is formed with at least one of an align key, an overlay key, and monitoring keys for various processes for performing a photo-lithography process. Further, the scribe line region 11 may be formed with electrical test patterns for process monitoring and feedback that is used after the photo-lithography process completes.

According to an embodiment such as shown in FIG. 2, protective patterns 20 for inhibiting plasma arching defects are formed in the scribe line region 11.

The protective patterns 20, which are connected to each other along an outside of the main chip region 12, are electrically connected from a top layer to a bottom layer of the wafer 10.

The protective pattern 20 is formed in a region other than a region in which various keys are formed in the scribe line region 11.

The protective pattern 20 may be simultaneously formed with the device forming process in the main chip region 11.

Referring to FIG. 2, the main chip region 12 and the scribe line region 11 is defined on a semiconductor substrate 30.

As an example embodiment, the main chip region on the semiconductor substrate 30 is formed with a gate oxide layer 61, a gate electrode 62 formed on the gate oxide layer 61, and a spacer 67 formed on a side wall of the gate electrode 62.

In the semiconductor substrate 30, a device isolation layer 31 is formed in a region other than an active region. The device isolation layer 31 may be formed by forming a trench by selectively etching the semiconductor substrate 30, and then burying an isolation layer in the trench.

The device isolation layer 31 may be formed in the main chip region 12 to isolate the devices as well as formed along a boundary between the scribe line region 11 and the main chip region 12.

The device isolation layer 31 formed in the scribe line region 11 (or along the boundary between the scribe line region 11 and the main chip region 12) may be formed to be deeper than the device isolation layer 31 formed in the main chip region 12.

The device isolation layer formed in the scribe line region 31 is formed to inhibit a high current generated by the plasma arching occurring in the scribe line region from damaging the main chip region.

In other words, the device isolation layer formed in the main chip region is used to isolate between the devices, while the device isolation layer formed in the scribe line region is used to isolate between the main chip region and the scribe line region.

Therefore, it is preferable that a device isolation layer 31 is formed along the boundary of the main chip region 12.

In the scribe line region 11, a first conductive type ion implantation region 35 and a second conductive type ion implantation region 33 below the first conductive type ion implantation region 35 can be formed on the semiconductor substrate 30.

Thereby, the first conductive type ion implantation region 35 and the second conductive type ion implantation region 33 may form a PN junction diode.

The first conductive type ion implantation region 35 and the second conductive type ion implantation region 33 may be formed together with the ion implantation process used in forming the devices in the main chip region 12.

For example, the PN junctioned first conductive type ion implantation region 35 and the second conductive type ion implantation region 33 may be formed in a vertical direction by selectively opening the scribe line region 11 and implanting impurities therein during the ion implantation process for forming a well 63 of the main chip region 12 and the ion implantation process for forming source and drain regions 65.

Meanwhile, the PN diode is not necessarily formed in the first conductive type ion implantation region 35 and the second conductive type ion implantation region 33. Therefore, the high current generated by the plasma arching can be bypassed by only the connection between the protective pattern 20 to the semiconductor substrate 30.

In the main chip region 12, a first insulating layer 41 is formed on the semiconductor substrate 30, and a contact electrode 51 is formed in a contact hole in the first insulating layer 41 to connect to the semiconductor substrate.

In the scribe line region 11, a plurality of first holes and first metal patterns 71 formed in the first holes are formed in the first insulating layer 41 formed on the semiconductor substrate 30.

The first metal pattern 71 is connected to the PN junction diode.

The first hole in the scribe line region and the contact hole in the main chip region may be formed by the same process. The first hole may be larger than the contact hole.

The first metal pattern 71 and the contact electrode 51 may be formed by the same process.

Then, in the main chip region 12, a first wiring 53 connected to the contact electrode 51 is formed on the first insulating layer 41.

In the scribe line region 11, a first protective line 73 connected to the first metal patterns 71 is formed on the first insulating layer 41.

The first wiring 53 and the first protective line 73 may be formed by the same process.

The second insulating layer 42 is formed over the semiconductor substrate 30 to cover the first wiring 53 and the first protection line 73.

In the main chip region 12, a first via hole connecting to the first wiring 53 is formed in the second insulating layer 42, and a first via electrode 55 is formed in the first via hole.

In the scribe line region 11, a plurality of second holes connecting to the first protective line 53 are formed in the second insulating layer 42, and second metal patterns 75 are formed in the second hole.

The first via hole and the second holes may be formed by the same process.

The first via electrode 55 and the second metal patterns 75 may be formed by the same process.

In the main chip region 12, a second wiring 57 connecting to the first via electrode 55 is formed on the second insulating layer 42.

In the scribe line region 11, a second protective line 77 connecting to the second metal patterns 75 is formed on the second insulating layer 42.

Thereafter, a third insulating layer 43 is formed on the second insulating layer 42 to cover the second wiring 57 and the second protective line 77.

In order to form the via hole on the third insulating layer 43, a dry etching process using plasma is performed. In this process, the plasma arching may occur.

Herein, the current generated by the plasma arching may be removed by the protective pattern 20, which includes the first impurity ion implantation region 35, the second impurity ion implantation region 33, the first metal patterns 71, the first protective line 73, the second metal patterns 75, and the second protective line 77, all of which are formed in the scribe line region 11.

The plasma arching defect may occur in the process as well as occur in other processes using plasma.

According to an embodiment, the protective patterns 20 are connected to each other through the semiconductor substrate 30 on which the first impurity ion implantation region 35, the second impurity ion implantation region 33, the metal patterns and the protective lines are formed.

In other words, the protective pattern 20 is formed by sequentially stacking the metal pattern and the protective line pattern by the same processes as the main chip region forming process, and protects the main chip region 12 from the plasma arching defect.

Each of the protective patterns 20 formed in the scribe line region 11 can be formed to have a larger width than the pattern formed in the main chip region 12. Therefore, the scribe line region 11 is opened wider than the main chip region 12 by the photo resist pattern 80. Thus, during the plasma etching, the insulating layer of the wider opened scribe line region 11 is removed faster in the etching process than the insulating layer of the opened main chip region 12. Therefore, before the metal pattern of the main chip region 12 is exposed, the metal of the protective pattern 20 in the scribe line region 11 is exposed faster.

Therefore, the electron charge caused by the generation of self DC bias is transferred to the PN junction diode generated in the scribe region through the protective pattern, and flows to the silicon substrate through the PN junction diode. This current can be discharged to the outside of the wafer through an electrostatic chuck (ESC) 90.

Therefore, the current generated by the plasma arching to the protective pattern 20 responding to plasma in the process using plasma can be discharged to the outside of the wafer, thereby making it possible to protect the main chip.

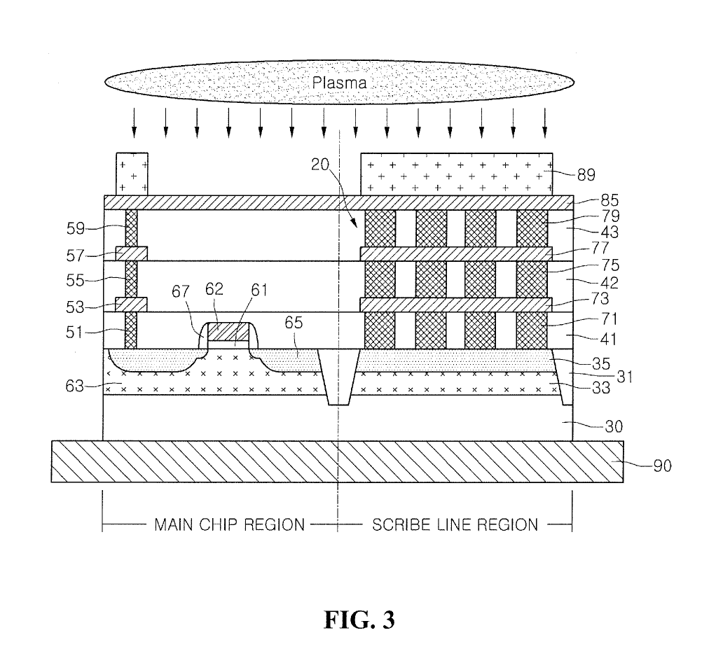

FIG. 3 is a cross-sectional view showing a plasma etching process of a semiconductor device according to another embodiment.

The semiconductor device shown in FIG. 3 can be understood with reference to the description of the semiconductor device shown in FIG. 2. In the semiconductor device shown in FIG. 3, a process of forming a metal line is added as a subsequent process of FIG. 2.

A third insulating layer 43 is formed on the second insulating layer 42. In the main chip region 12, a second via electrode 59 connected to the second wiring 57 is formed in the third insulating layer 43 and a third metal pattern 79 connected to the second protective line 77 is formed in the scribe line region 11.

A metal layer 85 for forming the metal line in the main chip region and the protective line in the scribed line region is formed on the third insulating layer 43.

In order to pattern the metal layer 85, a photo resist pattern 89 is formed on the metal layer 85.

In the plasma etching process for etching the metal layer 85 using the photo resist pattern 89, when the high current is generated by the plasma arching, the high current bypasses to the protective pattern 20, thereby making it possible to reduce defects due to the electron discharge.

In addition, the plasma damage occurring in the plasma etching process can be reduced, and in particular, the voltage retention fail, etc. due to the plasma damage can be reduced by inserting the protective pattern 20 into the scribe line (or a non-used region of the outside of the main chip when it is applied to the flash memory process into which the protective circuit is not inserted).

According to an embodiment, a separate further process is not needed since the protective pattern 20 can be formed together with the device forming process of the main chip region 12.

In addition, in the process of forming the protective pattern 20, the test patterns including the align key, the overlay key, the monitoring key, etc., may be formed in the scribe line region 11.

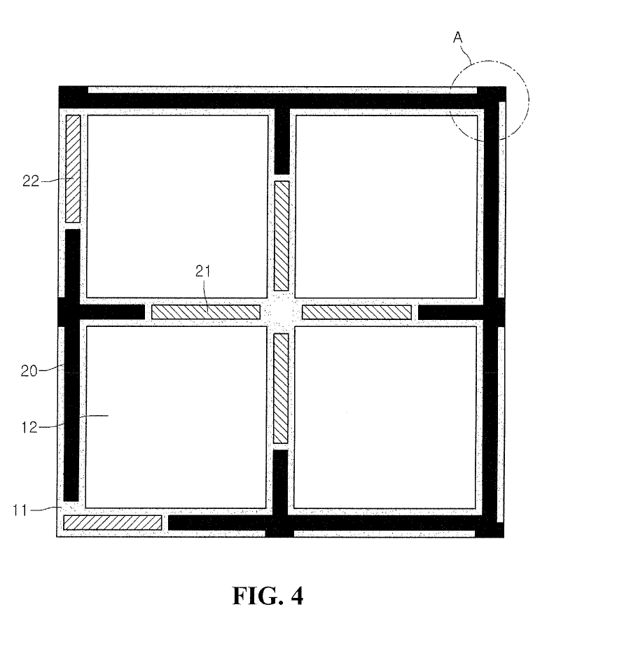

FIG. 4 is a plan view showing four main chip regions and the scribe line region at the circumference thereof in the semiconductor device according to an embodiment.

Generally, in the photo-lithography process, the region corresponding to one shot in exposure includes four main chip regions 12 and the scribe line region at the circumferences thereof.

As such, the device and the protective patter are formed on the semiconductor substrate by the patterning process through the photo process.

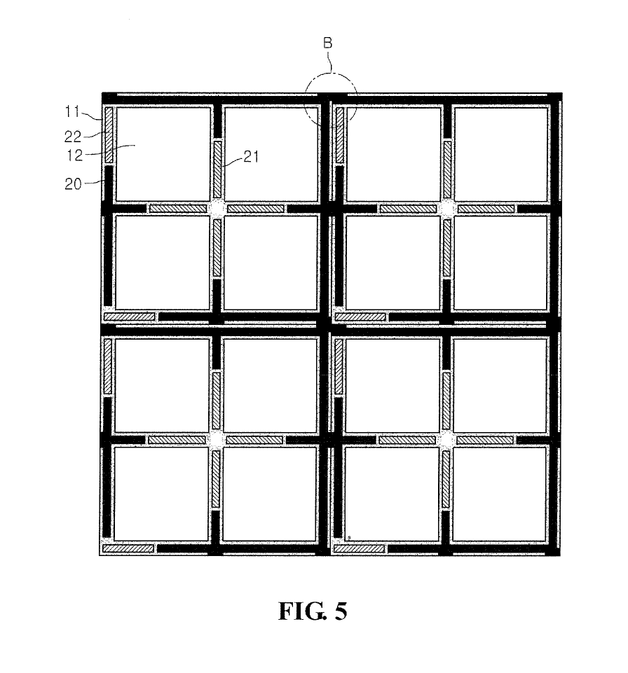

Referring to ‘A’ of FIG. 4, it can be appreciated that an edge portion of each shot is formed thickly. In other words, this is designed to be considered when forming the mask. In addition, when each shot is disposed, it can be appreciated that each protective pattern 20 is connected to be short-circuited from each other at ‘B’ portion of FIG. 5.

In other words, at least one portion at the outermost edge of each shot may be formed to be thicker than the thickness of other portions.

Thereby, when each shot is disposed, each protective pattern 20 may be continuously connected to each other. In particular, each protective pattern 20 may be connected to each other in the scribe line region 11 of a portion where one main chip region 12 meets the vertexes of other main chip regions 12.

The protective patterns 20 formed in the scribe line region 11 on the semiconductor substrate are electrically connected to each other over the wafer, such that the plasma arching can be removed without generating a main chip defect through the electrostatic chuck 90 below the substrate by using the protective pattern 20 formed in the scribe line region 11.

The protective pattern 20 may be formed in the scribe line region using the non-used region of the scribe line in a region other than the region in which align key 22 and the monitoring key 21 are formed.

The protective patterns 20 can be electrically connected to each other on the wafer.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A semiconductor device comprising:
a protective pattern grounded to a semiconductor substrate in a scribe line region, on a wafer that includes a main chip region and the scribe line region formed around the main chip region.

2. The semiconductor device according to claim 1, wherein the protective pattern comprises a metal pattern and a protective line formed by a process of forming a via metal and a metal wiring in the main chip region.

3. The semiconductor device according to claim 2, wherein the metal pattern and the protective line are electrically connected to the semiconductor substrate and are electrically connected to a top metal layer.

4. The semiconductor device according to claim 1, wherein the protective pattern comprises:
a first metal pattern formed in a first insulating layer on the semiconductor substrate, the first metal pattern connected to the semicondcutor substrate;
a first protective line formed on the first insulating layer and connected to the first metal pattern;
a second metal pattern formed in a second insulating layer formed on the first insulating layer, wherein the second metal pattern is connected to the first protective line; and
a second protective line formed on the second insulating layer and connected to the second metal pattern.

5. The semiconductor device according to claim 4, wherein the main chip region comprises:
a first via metal formed in the first insulating layer and having a width smaller than the first metal pattern;
a first metal wiring formed on the first insulating layer and connected to the first via metal;
a second via metal aimed in the second insulating layer and having a width smaller than the second metal pattern; and
a second metal wiring formed on the second insulating layer and connected to the second via metal.

6. The semiconductor device according to claim 1, wherein the protective pattern is electrically connected on a front surface of the wafer.

7. The semiconductor device according to claim 1, further comprising a PN junction diode formed in the semiconductor substrate in the scribe line region, wherein the protective pattern is grounded to the semiconductor substrate through the PN junction diode.

8. The semiconductor device according to claim 1, wherein the scribe line region further comprises at least one of an align key, an overlay key, and a monitoring pattern.

9. The semiconductor device according to claim 1, further comprising a device isolation layer in the semiconductor substrate along a boundary between the main chip region and the scribe line region.

10. A method of manufacturing a semiconductor device, comprising:
during a process of forming a via metal and a metal wiring of a semiconductor device on a semicondcutor substrate in a main chip region of a wafer, forming a protective pattern of a metal pattern and a protective line in a scribe line region of the wafer, the metal pattern contacting the semiconductor substrate.

11. The method according to claim 10, wherein the protective pattern is electrically connected to a top metal layer and the semiconductor substrate.

12. The method according to claim 10, further comprising:
forming a first insulating layer on the semiconductor substrate and forming in the first insulating layer a first via metal in the main chip region and a first metal pattern having a wider width than the first via metal in the scribe line region;
forming a first protective line and a first metal line on the first insulating layer, wherein the first metal line is connected to the first via metal in the main chip region and the first protective line is connected to the first metal pattern in the scribe line region; and
forming a second insulating layer on the first insulating layer and forming in the second insulating layer a second via metal connected to the first metal line in the main chip region and a second metal pattern connected to the first protective line in the scribe line region.

13. The method according to claim 10, wherein the protective pattern is electrically connected on a front surface of the wafer.

14. The method according to claim 10, further comprising forming a trench along a boundary between the main chip region and the scribe line region on the semiconductor substrate, and forming a device isolation layer buried in the trench.

15. The method according to claim 10, further comprising forming a first impurity ion implantation region in the scribe line region and a second impurity ion implantation region below the first impurity ion implantation region.

16. A semiconductor device, comprising:
transistors formed on a semiconductor substrate in a main chip region;
a metal wiring layer formed on the semiconductor substrate in the main chip region, the metal wiring layer comprising metal wirings connected to the transistors; and
a protective pattern formed on the metal wiring layer in a scribe line region outside the main chip region, wherein the protective pattern is grounded to the semiconductor substrate and is connected to a top layer of the metal wiring layer.
